(19) United States
(12) Patent Application Publication
(10) Pub. No.: US 2017/0271134 A1
(43) Pub. Date: Sep. 21, 2017

(54) Lithium Cobalt Sintered Body and Sputtering Target Produced by Using the Sintered Body, Production Method of Lithium Cobalt Oxide Sintered Body, and Thin Film Formed from Lithium Cobalt Oxide

(71) Applicant: JX Nippon Mining & Metals Corporation, Tokyo (JP)

(72) Inventors: Yosuke Endo, Ibaraki (JP); Kazuyuki Sato, Ibaraki (JP); Ryo Suzuki, Ibaraki (JP)

(21) Appl. No.: 15/439,402

(22) Filed: Feb. 22, 2017

(30) Foreign Application Priority Data
Mar. 17, 2016 (JP) 2016-053865

(51) Int. Cl. H01J 37/34; C01G 51/00; B28B 11/24; C23C 14/34; H01M 4/04

(52) U.S. Cl. CPC H01J 37/3426; C23C 14/3414; H01J 37/3435; H01M 4/0426; B28B 11/243; C01G 51/42; B28B 3/02

(57) ABSTRACT

A lithium cobalt oxide sintered body having a bending strength of 100 MPa or more, and a sputtering target formed using the sintered body are provided. In particular, a cylindrical sputtering target for use in rotary sputtering is provided. The sputtering target is useful in forming a cathode material thin film in an all-solid thin film lithium ion secondary battery for use in vehicles, telecommunication equipment and household equipment.

### BACKGROUND

The present invention relates to a lithium cobalt oxide sintered body and a sputtering target produced by using the sintered body, a method of producing the lithium cobalt oxide sintered body, and a thin film formed from a lithium cobalt oxide, and in particular relates to a sputtering target which is suitable for forming a thin film cathode for use in a thin film battery such as an all-solid battery, and a method of producing such a sputtering target.

A lithium ion secondary battery is attracting attention as a high output, large capacity secondary battery, and various R&D activities are being actively conducted. While electrodes and electrolytes configuring the lithium ion secondary battery face numerous challenges from the perspective of energy density, charge-discharge properties, production process, and material costs, an all-solid lithium ion battery which is produced by replacing liquid electrolytes, which are combustible and in which the possibility of fires resulting from a liquid spill is being point out, with solid electrolytes, is attracting attention.

Generally speaking, the ion conductance of solid electrolytes is lower by several orders of magnitude in comparison to liquid electrolytes, and this is a major impediment in the practical application of an all-solid lithium ion battery. And today, numerous research institutions and corporations are actively developing materials concentrating on solid electrolytes having high ionic conductivity. In recent years, an all-solid thin film lithium ion secondary battery which resolved the drawback of having low ionic conductivity has been developed and marketed by forming the solid electrolytes as thin films.

An all-solid thin film battery yields the following characteristics; specifically, it is thin, it can be miniaturized, deterioration is minimal, and there is no problem of a liquid spill. The cathode materials and solid electrode films configuring this type of thin film lithium ion battery are produced via the sputtering method. The sputtering method has advantages in that the adjustment of deposition conditions is easy, and films can be easily deposited on a substrate. The present Applicant has previously provided a technology related to a target formed from a lithium-containing transition metal oxide capable of forming highly uniform films and with minimal generation of particles during sputtering (see Japanese Patent No. 5433044).

Various types of research are being conducted for improving the sputtering properties in relation to a target formed from a lithium cobalt oxide and, for instance, Japanese Patent Application Publication No. 2013-194299 describes that, by reducing impurities and attaining a relative density of 95% or more and a specific resistance of less than 2×10⁷ Ωcm, it is possible to stably deposit films at a high deposition rate without any generation of abnormal discharge. Furthermore, Japanese Patent Application Publication No. 2014-198901 describes that, by increasing the area ratio occupied by pores in a large-sized LiCoO₂-containing sputtering target, it is possible to suppress the variation in the specific resistance and deposit films at a high deposition rate. Also, see Japanese Patent Application Publication No. 2014-231639

### SUMMARY

During sputtering, there are cases where cracks (fractures) are generated in a sputtering target due to the high stress that is applied on the target. In particular, since a target for use in rotary sputtering is sputtered at a higher energy in comparison to a conventional planar type target, the stress applied on a rotary target will increase. Thus, a rotary target needs to have high strength in comparison to a planar target. Note that a rotary target refers to a cylindrical target, and is used by bonding to a titanium backing tube or the like, and a planar target refers to a target including a plate shape target and a disk shape target, and is used by being bonded to a copper backing plate or the like.

Nevertheless, the targets described in the foregoing prior art documents are unable to satisfy the required strength, and encountered problems such as the generation of cracks and the increase of particles (microscopic floating materials) during sputtering. Note that, while Patent Document 4 describes a Li-containing oxide target having a bending strength of 20 MPa or more, the highest bonding strength disclosed in its Examples is only 62 MPa, and this level of bending strength is insufficient for rotary sputtering.

Normally, when producing a sintered body (sputtering target) having a high density or high strength, the hot press method is adopted. Even in cases of a cylindrical sputtering target for use in rotary sputtering, considered may be producing the sintered body by placing a powder between a die and a core and performing hot press thereto. Nevertheless, with this method, since the core will become contracted and tightened during the sintering process and cracks will be generated in the sintered body, it was not possible to produce a high strength cylindrical target based on the hot press method. The present invention was devised in order to resolve the foregoing problems, and an object of this invention is to provide a sputtering target having a high strength and capable of stable sputtering, as well as provide a method of producing such a sputtering target and a thin film produced from such a sputtering target.

In order to achieve the foregoing object, as a result of intense study, the present inventors discovered that a high strength sputtering target can be obtained by devising the production method in the production process of a sputtering target formed from a lithium cobalt oxide. Based on the foregoing discovery, the present inventors provide the following invention. 1) A lithium cobalt oxide sintered body, wherein the sintered body has a bending strength of 100 MPa or more. 2) The lithium cobalt oxide sintered body according to 1) above, wherein an average value of a bulk resistance of the sintered body is 100 Ω•cm or less. 3) The lithium cobalt oxide sintered body according to 1) or 2) above, wherein the sintered body has a relative density of 87% to 94%. 4) The lithium cobalt oxide sintered body according to any one of 1) to 3) above, wherein the sintered body is of a cylindrical shape. 5) The lithium cobalt oxide sintered body according to any one of 1) to 3) above, wherein the sintered body is of a planar shape. 6) A sputtering target formed using the sintered body according to any one of 1) to 5) above. 7) A method of producing a lithium cobalt oxide sintered body, wherein a granulated powder of a lithium cobalt oxide is subject to press molding, and an obtained molded body is sintered at 1000 to 1100° C. in an atmosphere containing oxygen in an amount of 99 vol % or more. 8) The method of producing a lithium cobalt oxide sintered body according to 7) above, wherein a lithium cobalt oxide slurry is spray-dried to prepare a granulated powder having an average grain size of 20 to 150 μm. 9) The method of producing a lithium cobalt oxide sintered body according to 8) above, wherein the granulated powder of the lithium cobalt oxide is subject to cold press and/or CIP molding. 10) A method of producing a sputtering target produced using a lithium cobalt oxide sintered body, wherein the lithium cobalt oxide sintered body produced with the production method according to any one of 7) to 9) above is machined into a target shape and thereafter bonded to a backing plate or a backing tube, and a surface to be sputtered of the sputtering target is subject to cutting or grinding in a thickness of 0.1 to 1.0 mm 11) A lithium cobalt oxide thin film produced using the sputtering target according to 6) above.

Because the sputtering target of the present invention formed from a lithium cobalt oxide, which is suitable forming cathode material thin films for use in an all-solid thin film lithium ion secondary battery and the like, is of high strength and enables stable sputtering, it is possible to deposit uniform films. Furthermore, since the sputtering target of the present invention has low bulk resistance and high relative density, it can be used in DC sputtering capable of high-speed deposition, and yields a superior effect of being able to improve the productivity. The present invention is particularly useful in a cylindrical target for use in rotary sputtering.

### BRIEF DESCRIPTION OF DRAWINGS

FIG. 1 is a schematic diagram showing the measurement locations of the bending strength and bulk resistivity of a cylindrical sputtering target.

FIG. 2 is a schematic diagram showing the measurement locations of the bending strength and bulk resistivity of a plate-shaped sputtering target.

FIG. 3 is a schematic diagram showing the measurement locations of the bending strength and bulk resistivity of a disk-shaped sputtering target.

### DETAILED DESCRIPTION

The lithium cobalt oxide sintered body of the present invention is characterized in having a bending strength of 100 MPa or more. Since a sputtering target produced using this kind of sintered body having a high strength can inhibit the generation of cracks, it is possible to reduce the generation of abnormal discharge and particles during sputtering, and enable stable sputtering. In particular, this kind of sintered body target having a bending strength of 100 MPa or more is effective as a cylindrical rotary sputtering target which is demanded of a high strength. Note that, with rotary sputtering, a cylindrical target material (piece) is bonded to a backing tube by being stacked in multiple layers in the longitudinal direction.

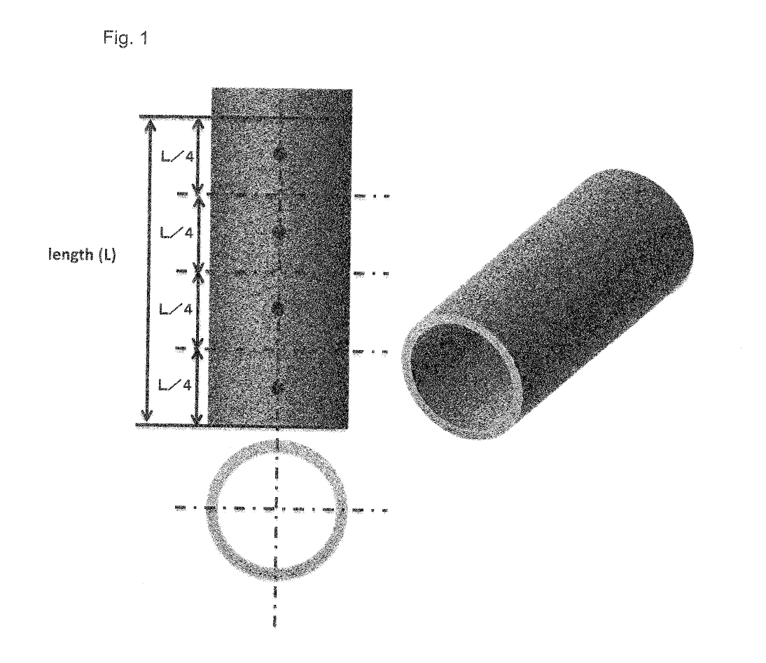

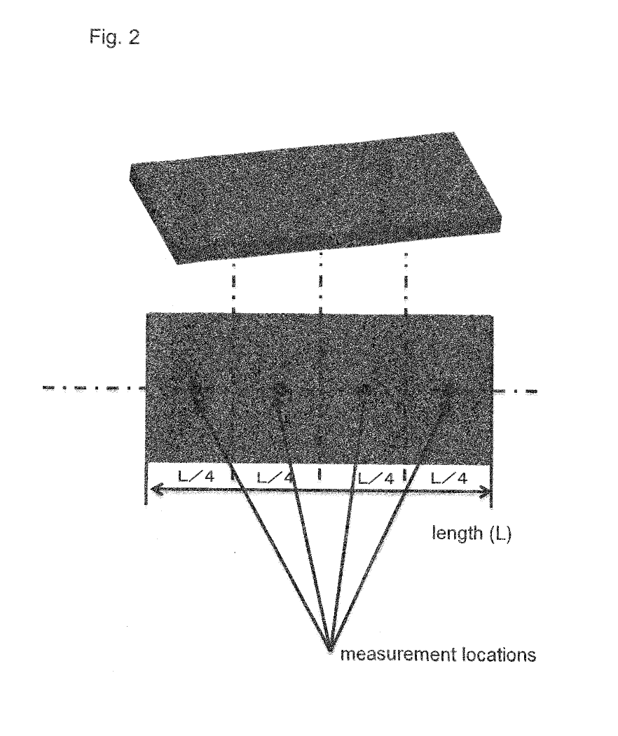

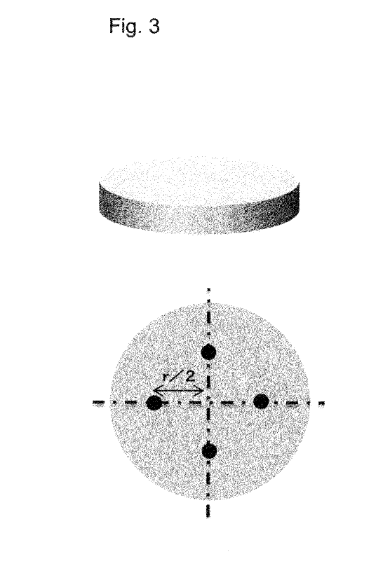

The bending strength in the present invention was measured by cutting test pieces (height: 3.0 (±0.1) mm, width: 4.0 (±0.1) mm, length: 40 mm) from four locations of a target piece as shown in FIGS. 1 to 3, and measuring the bending strength of the respective test pieces based on the three-point bending strength measurement method described in JIS R1601, and the average value of the measured values was taken. Note that, in the case of a rotary target, the test pieces were collected so that, of the dimension of the test pieces, the height will be the plate thickness direction and the length will be the longitudinal direction, and, in the case of a planar target, the test pieces were collected so that the height will be the plate thickness direction.

Moreover, with the lithium cobalt oxide sintered body of the present invention, the average value of the bulk resistance is preferably 100 Ω•cm or less, and more preferably 80 Ω•cm or less. A sputtering target produced by using this kind of low resistance sintered body can be applied to DC sputtering which enables stable, high-speed deposition, and can improve the productivity. The bulk resistance in the present invention was measured by measuring four locations of a target piece based on the four-terminal sensing method as shown in FIGS. 1 to 3, and the average value of the measured values was taken.

The lithium cobalt oxide sintered body (true density: 5.05 g/cm³) of the present invention preferably has a relative density (measured density/true density×100) of 87% or more, and more preferably a relative density of 90% or more. A sputtering target produced by using this kind of high density sintered body enables stable sputtering which is free from abnormal discharge. Moreover, a high density target can be used in DC sputtering which enables high-speed deposition in combination with the foregoing resistance value of the target, and thereby improve the productivity. In the present invention, the measured density of the sintered body was measured based on the

Archimedes method. Note that, while a higher density is preferable, in effect, the upper limit thereof is roughly 94%.

The lithium cobalt oxide sintered body (target) of the present invention needs to be of a cylindrical shape for use in rotary sputtering. The sintered body (sputtering target) of the present invention is able to achieve high strength, low resistance, and high density even when formed in this kind of cylindrical shape, and the high strength sintered body in the present invention is particularly effective as a cylindrical target for use in rotary sputtering. Needless to say, the lithium cobalt oxide sintered body of the present invention may also be of a planar shape (plate shape, disk shape) for use in standard sputtering.

The lithium cobalt oxide sintered body of the present invention can be produced as follows. Foremost, water and PVA (polyvinyl alcohol) are added to a lithium cobalt oxide raw material powder having a predetermined LiCo ratio to prepare a lithium cobalt oxide slurry. Next, the lithium cobalt oxide slurry (containing PVA) is spray-dried to prepare a granulated powder having an average grain size of 20 to 150 μm. Here, when the average grain size is less than 20 μm, it is difficult for the density of the molded body to increase after processes such as cold press and CIP, and, because the powder is light, there are cases where the yield during granulation becomes inferior. Meanwhile, when the average grain size exceeds 150 μm, the density of the molded by after processes such as cold press and CIP may deteriorate, and this is undesirable.

Next, the obtained granulated powder is subject to cold press and/or CIP (cold isostatic press) to prepare a molded body. In particular, when forming a cylindrical shape, the granulated powder is preferably subject to CIP molding to obtain a molded body, and when forming a plate shape, the granulated powder is preferably subject to cold press and thereafter subject to CIP molding to obtain a molded body. Here, the pressure is preferably 20 to 50 MPa in the case of performing cold press, and the pressure is preferably 100 to 170 MPa when performing CIP.

Next, the molded body of the lithium cobalt oxide obtained as described above is sintered at 1000° C. to 1100° C. in an oxygen atmosphere to prepare a sintered body. When the sintering temperature is less than 1000° C., the density of the sintered body cannot be increased. Meanwhile, when the sintering temperature exceeds 1100° C., the lithium cobalt oxide will decompose and cause the bending strength of the sintered body to deteriorate and cause the bulk resistance to increase, and this is undesirable. By performing sintering within the foregoing optimal temperature range, it is possible to obtain a high strength lithium cobalt oxide sintered body. Moreover, the sintering time is preferably 20 hours or more and 40 hours or less. When the sintering time is less than 20 hours, sintering will not progress sufficiently, and when the sintering time exceeds 40 hours, the decomposition of the lithium cobalt oxide may progress.

After subjecting the thus obtained sintered body to machining (cutting, polishing or the like) to obtain a target shape, it is bonded to a backing plate in a disk shape or a plate shape or a backing tube in a cylindrical shape to prepare a sputtering target assembly. Thereafter, the surface to be sputtered of the target is subject to cutting or grinding in a thickness of 0.1 to 1.0 mm to remove the altered layer, whereby the target is finished.

### EXAMPLES

The present invention is now explained based on Examples and Comparative Examples. Note that the following Examples are merely exemplifications, and the present invention is not limited to such Examples. In other words, the present invention is limited only based on the scope of its claims, and the present invention also covers the other modes and modifications included therein.

### Example 1

Water and PVA were added to a lithium cobalt oxide raw material powder to attain a solid content of 50 mass% and prepare a lithium cobalt oxide slurry. Next, the prepared lithium cobalt oxide slurry was dried with a spray dryer to obtain a granulated powder having an average grain size of 50 μm. Subsequently, the obtained granulated powder was subject to CIP molding at a pressure of 120 MPa, and the obtained molded body was sintered at 1000° C. for 30 hours in an oxygen atmosphere to prepare a cylindrical sintered body formed from a lithium cobalt oxide having an outer diameter of 160 mm, an inner diameter of 130 mm, and a length of 260 mm.

As a result of measuring the bending strength of the obtained sintered body with a tensile and compression testing machine (manufactured by Imada-SS Corporation, model SV-201NA-50SL), the average value of the bending strength was 105 MPa. Moreover, the relative density of the sintered body was 87%. Next, a sintered body prepared according to the same method was subject to cutting work and finished as a cylindrical target piece having an outer diameter of 151 mm, an inner diameter of 135 mm, and a length of 240 mm. As a result of measuring the bulk resistivity of this target piece, the average value was 11 0.cm. Subsequently, a total of six cylindrical target pieces were bonded to a titanium backing tube, a thickness of 0.5 mm was cut in order to remove the surface altered layer that was altered during bonding, and the bonded product was mounted on a sputtering device and sputtered. Consequently, DC sputtering was possible, arcing was not generated, and stable deposition was enabled. The foregoing results are shown in Table 1.

TABLE 1

| | | | Sintering | Sintering | | |
|---|---|---|---|---|---|---|
| | | | Temperature | Time | Pressure | Sintered Body |
| | Sintering | Shape | [° C.] | [h] | [kgf/cm²] | Size [mm] |
| Example 1 | Pressureless | Cylinder | 1000 | 30 | — | O.D.φ160 × I.D.φ130 × 260L |
| | sintering | | | | | |
| Example 2 | Pressureless | Cylinder | 1050 | 30 | — | O.D.φ160 × I.D.φ130 × 260L |
| | sintering | | | | | |
| Example 3 | Pressureless | Cylinder | 1100 | 30 | — | O.D.φ160 × I.D.φ130 × 260L |
| | sintering | | | | | |
| Example 4 | Pressureless | Cylinder | 1050 | 20 | — | O.D.φ160 × I.D.φ130 × 260L |
| | sintering | | | | | |
| Example 5 | Pressureless | Cylinder | 1050 | 40 | — | O.D.φ160 × I.D.φ130 × 260L |
| | sintering | | | | | |
| Example 6 | Pressureless | Cylinder | 1050 | 30 | — | O.D.φ160 × I.D.φ130 × 400L |
| | sintering | | | | | |
| Example 7 | Pressureless | Disk | 1050 | 30 | — | φ220 × 12t |
| | sintering | | | | | |
| Comparative | Hot press | Disk | 950 | 2 | 300 | φ220 × 12t |
| Example 1 | | | | | | |
| Comparative | Hot press | Disk | 1050 | 2 | 300 | φ220 × 12t |
| Example 2 | | | | | | |
| Comparative | Pressureless | Cylinder | 1200 | 30 | — | O.D.φ160 × I.D.φ130 × 260L |
| Example 3 | sintering | | | | | |
| Comparative | Pressureless | Cylinder | 950 | 30 | — | O.D.φ160 × I.D.φ130 × 260L |
| Example 4 | sintering | | | | | |

| | | | Average | | |
|---|---|---|---|---|---|
| | | Relative | Bulk | Bending | |
| | | Density | Resistance | Strength | DC |
| | Atmosphere | [%] | [Ω · cm] | [Mpa] | Sputtering |
| Example 1 | Oxygen | 87 | 11 | 105 | ∘ |
| Example 2 | Oxygen | 90 | 19 | 125 | ∘ |
| Example 3 | Oxygen | 94 | 97 | 118 | ∘ |
| Example 4 | Oxygen | 89 | 17 | 117 | ∘ |
| Example 5 | Oxygen | 91 | 22 | 123 | ∘ |
| Example 6 | Oxygen | 90 | 27 | 123 | ∘ |
| Example 7 | Oxygen | 89 | 20 | 124 | ∘ |
| Comparative | Vacuum | 95 | 270 | 57 | x |
| Example 1 | | | | | |
| Comparative | Vacuum | 96 | 1106 | 53 | x |
| Example 2 | | | | | |
| Comparative | Oxygen | 94 | 1256 | 90 | x |
| Example 3 | | | | | |
| Comparative | Oxygen | 86 | 11 | 93 | ∘ |
| Example 4 | | | | | |

### Examples 2 to 6

In the same manner as Example 1, water and PVA were added to a lithium cobalt oxide raw material powder to attain a solid content of 50 mass% and prepare a lithium cobalt oxide slurry. Next, the prepared lithium cobalt oxide slurry was dried with a spray dryer to obtain a granulated powder having an average grain size of 50 μm. Subsequently, the obtained granulated powder was subject to CIP molding at a pressure of 120 MPa, and the obtained molded body was sintered in an oxygen atmosphere to prepare a cylindrical sintered body formed from a lithium cobalt oxide having an outer diameter of 160 mm, an inner diameter of 130 mm, and a length of 260 mm (Example 6 had a length of 400 mm). In Examples 2 to 6, sintered bodies were prepared by changing the sintering temperature and the sintering time as shown in Table 1.

As a result of measuring the bending strength of the obtained sintered body in the same manner as Example 1, the average value of the bending strength was 100 MPa in all cases. Moreover, the relative density of the sintered body was 87% or more in all cases. Next, sintered bodies prepared according to the same method were subject to cutting work and finished as cylindrical target pieces having an outer diameter of 151 mm, an inner diameter of 135 mm, and a length of 240 mm As a result of measuring the bulk resistivity of the target pieces, the average value was 100 Ω•cm or less in all cases. Subsequently, six cylindrical target pieces were bonded to a titanium backing tube, a thickness of 0.5 mm was cut in order to remove the surface altered layer that was altered during bonding, and the bonded product was mounted on a sputtering device and sputtered. Consequently, DC sputtering was possible, arcing was not generated, and stable deposition was enabled in all cases.

### Example 7

In the same manner as Example 1, water and PVA were added to a lithium cobalt oxide raw material powder to attain a solid content of 50 mass % and prepare a lithium cobalt oxide slurry. Next, the prepared lithium cobalt oxide slurry was dried with a spray dryer to obtain a granulated powder having an average grain size of 50 μm. Next, the obtained granulated powder was subject to cold press at a pressure of 25 MPa and thereafter subject to CIP molding at a pressure of 150 MPa to prepare a molded body. Subsequently, the obtained molded body was sintered at 1050° C. and for 30 hours in an oxygen atmosphere to prepare a disk-shaped sintered body formed from a lithium cobalt oxide having a diameter of 220 mm and a thickness of 12 mm.

As a result of measuring the bending strength of the obtained sintered body in the same manner as Example 1, the average value of the bending strength was 124 MPa. Moreover, the relative density of the sintered body was 89%. Next, a sintered body prepared according to the same method was subject to cutting work and finished as a disk-shaped target having a diameter of 203.5 mm and a thickness of 5.5 mm. As a result of measuring the bulk resistivity of the target, the average value was 20 Ω•cm. Subsequently, the disk-shaped target was bonded to a copper backing plate, a thickness of 0.5 mm was cut in order to remove the surface altered layer that was altered during bonding, and the bonded product was mounted on a sputtering device and sputtered. Consequently, DC sputtering was possible, arcing was not generated, and stable deposition was enabled.

### Comparative Examples 1 and 2

In the same manner as Example 1, water and PVA were added to a lithium cobalt oxide raw material powder to attain a solid content of 50 mass% and prepare a lithium cobalt oxide slurry. Next, the prepared lithium cobalt oxide slurry was dried with a spray dryer to obtain a granulated powder having an average grain size of 50 gm. Subsequently, the obtained granulated powder was filled in a carbon mold and subject to hot press sintering under the following conditions; specifically, in a vacuum, at 950° C. (Comparative Example 1) or 1050° C. (Comparative Example 2), for 2 hours, and at a pressure of 300 kgf/cm² to prepare a disk-shaped sintered body formed from a lithium cobalt oxide having a diameter of 220 mm and a thickness of 12 mm.

As a result of measuring the bending strength of the obtained sintered body in the same manner as Example 1, the average values of the bending strength were low values at 57 MPa and 53 MPa, respectively. Next, sintered bodies prepared according to the same method were subject to cutting work and finished as disk-shaped targets having a diameter of 203.5 mm and a thickness of 5.5 mm. As a result of measuring the bulk resistivity of the targets, the average value considerably exceeded 100 Ω•cm in all cases. Subsequently, the disk-shaped targets were bonded to a copper backing plate, a thickness of 0.5 mm was cut in order to remove the surface altered layer that was altered during bonding, and the bonded product was mounted on a sputtering device and sputtered. Consequently, DC sputtering was not possible or discharge was unstable, and stable deposition could not be performed.

### Comparative Examples 3 and 4

In the same manner as Example 1, water and PVA were added to a lithium cobalt oxide raw material powder to attain a solid content of 50 mass % and prepare a lithium cobalt oxide slurry. Next, the prepared lithium cobalt oxide slurry was dried with a spray dryer to obtain a granulated powder having an average grain size of 50 gm. Subsequently, the obtained granulated powder was subject to CIP molding at a pressure of 120 MPa, and the obtained molded body was sintered in an oxygen atmosphere to prepare a cylindrical sintered body formed from a lithium cobalt oxide having an outer diameter of 160 mm, an inner diameter of 130 mm, and a length of 260 mm. In Comparative Examples 3 and 4, sintered bodies were prepared by changing the sintering temperature and sintering time as shown in Table 1.

As a result of measuring the bending strength of the obtained sintered body in the same manner as Example 1, the average value of the bending strength was less than 100 MPa in all cases. Moreover, the relative density of the sintered body of Comparative Example 4 showed a low value at 86%. Next, sintered bodies prepared according to the same method were subject to cutting work and finished as cylindrical target pieces having an outer diameter of 151 mm, an inner diameter of 135 min, and a length of 240 mm As a result of measuring the bulk resistivity of the target piece, the average value of resistivity in Comparative Example 3 showed a high value at 1256 Ω•cm. Subsequently, six cylindrical target pieces were bonded to a titanium backing tube, a thickness of 0.5 mm was cut in order to remove the surface altered layer that was altered during bonding, and the bonded product was mounted on a sputtering device and sputtered. Consequently, DC sputtering was not possible, or stable deposition was not possible.

Because the lithium cobalt oxide sintered body and the sputtering target formed using the sintered body of the present invention are of high strength, hardly any cracks are generated, and they yield favorable sputtering characteristics. Moreover, since the sputtering target of the present invention has low resistivity and can be subject to DC sputtering, it is possible to deposit uniform thin films at a high rate. Moreover, since the sputtering target of the present invention has a high density, the generation of abnormal discharge (arcing) during deposition is minimal, and the generation of particles can be inhibited. An all-solid thin film lithium ion secondary battery adopting this kind of thin film yields an effect of being able to obtain stable charge-discharge characteristics. The present invention is particularly useful in a lithium ion secondary battery for use in vehicles, telecommunication equipment, household equipment and solar batteries.

1. A lithium cobalt oxide sintered body, wherein the sintered body has a bending strength of 100 MPa or more.

2. The lithium cobalt oxide sintered body according to claim 1, wherein an average value of a bulk resistance of the sintered body is 100 Ω•cm or less.

3. The lithium cobalt oxide sintered body according to claim 2, wherein the sintered body has a relative density of 87% to 94%.

4. The lithium cobalt oxide sintered body according to claim 3, wherein the sintered body is of a cylindrical shape.

5. The lithium cobalt oxide sintered body according to claim 3, wherein the sintered body is of a planar shape.

6. A sputtering target formed of the sintered body according to claim 5.

7. A sputtering target formed of the sintered body according to claim 4.

8. The lithium cobalt oxide sintered body according to claim 1, wherein the sintered body has a relative density of 87% to 94%.

9. The lithium cobalt oxide sintered body according to claim 1, wherein the sintered body is of a cylindrical shape.

10. The lithium cobalt oxide sintered body according to claim 1, wherein the sintered body is of a planar shape.

11. A sputtering target formed using the sintered body according to claim 1.

12. A lithium cobalt oxide thin film produced using the sputtering target according to claim 11.

13. A method of producing a lithium cobalt oxide sintered body, wherein a granulated powder of a lithium cobalt oxide is subject to press molding, and an obtained molded body is sintered at 1000 to 1100° C. for 20 hours or more and 40 hours or less in an atmosphere containing oxygen in an amount of 99 vol % or more.

14. The method of producing a lithium cobalt oxide sintered body according to claim 13, wherein a lithium cobalt oxide slurry is spray-dried to prepare a granulated powder having an average grain size of 20 to 150 μm.

15. The method of producing a lithium cobalt oxide sintered body according to claim 14, wherein the granulated powder of the lithium cobalt oxide is subject to cold press and/or CIP molding.

16. A method of producing a sputtering target, wherein the lithium cobalt oxide sintered body produced with the production method according to claim 15 is machined into a target shape and thereafter bonded to a backing plate or a backing tube, and a surface to be sputtered of the sputtering target is subject to cutting or grinding in a thickness of 0.1 to 1.0 mm.

17. The method of producing a lithium cobalt oxide sintered body according to claim 13, wherein the granulated powder of the lithium cobalt oxide is subject to cold press and/or CIP molding.

18. A method of producing a sputtering target, wherein the lithium cobalt oxide sintered body produced with the production method according to claim 13 is machined into a target shape and thereafter bonded to a backing plate or a backing tube, and a surface to be sputtered of the sputtering target is subject to cutting or grinding in a thickness of 0.1 to 1.0 mm.
